(19) United States
(12) Patent Application Publication
(10) Pub. No.: US 2007/0230128 A1
(43) Pub. Date: Oct. 4, 2007

(54) Cooling apparatus with surface enhancement boiling heat transfer

(75) Inventors: Jesse Kim, San Jose, CA (US); Seung Mun You, Arlington, TX (US)

Correspondence Address: Fernandez & Associates, LLP, PO Box D, Menlo Park, CA, 94025-6204, US

(73) Assignees: Vapro Inc., San Jose, CA (US); UNIVERSITY OF TEXAS

(21) Appl. No.: 11/398,197

(22) Filed: Apr. 4, 2006

(51) Int. Cl. H05K 7/20

(52) U.S. Cl. 361/699

(57) ABSTRACT

A cooling apparatus boiling and condensing liquid coolant has a vessel including a microporous surface enhancement coating applied on a thermally-conductive plate which is fully immersed under the liquid coolant in the vessel. The surface enhancement coating augments significantly a nucleate boiling heat transfer and critical heat flux when receiving heat from a heating object coupled to the thermally-conductive plate at a surface outside of the vessel. One embodiment of this invention including a vessel with a height/length dimension less than 300 mm, a microporous coating with nickel particles of 30-50 μm in size bonded by a thermally-conductive binder, and water as the liquid coolant, without complicated radiator component, is used for cooling a heating electronics element.

### BACKGROUND INFORMATION

1. Field of Invention

This invention relates to a boiling cooler for cooling a heating element by a two-phase heat transfer using liquid boiling, particularly to a cooling apparatus in small form factor for cooling heat-generating electronics elements in combination with a usage of boiling enhancement coating to increase the density of boiling nucleation sites, and a usage of economic liquid coolant like water.

2. Background of Invention

Several conventional cooling apparatuses for cooling a heating object by boiling and condensing a liquid coolant therein are known in the art, such as radiators or air conditioners in automobiles. One such boiling cooler comprises a tank or chamber as the liquid coolant container which is in contact with a heating object; a liquid coolant, usually refrigerant with low boiling temperature, to receive heat and boil to vaporization; and a radiator assembly connected to the tank serving as vapor passage holder and heat exchanger to condense vapor back to liquid. No specific surface boiling enhancement techniques have been adopted except for mechanically roughening the tank surfaces when cooling heat-generating electronics elements. The module design of those types of boiling coolers is mostly focused on improving the effectiveness of the radiator or heat exchanger configuration through complicated mechanical structural design to accelerate condensation process so that they can effectively handle substantially large heat flux. The size of these coolers usually is too large for cooling modern electronics devices.

One cooling apparatus has a simpler structure of a tall tower over a wide base vapor chamber used as heat sink for electronic devices such as CPU processors. But its cooling mechanism relies on evaporation not boiling of the liquid coolant including water. The volume of liquid coolant in this kind of cooler is relatively small comparing to that in boiling cooler. It has low dry-out point and low overall performance ceiling. This is problematic as heat intensity of the modern CPU processors increase.

Thermosyphon is another example for a phase-change cooler but it has a more complicated structure, including boiler, condenser, and pipe lines. It may not be as effective as passive two-phase cooling chambers.

The electronics industry, driven by the advancing computational capabilities with increasing electronic signal speed, is required to design miniaturized, highly integrated, high-density packaging components. This leads to higher component surface temperatures and elevated heat dissipation rates at chip, module, and system levels. Suitable cooling modules for cooling a variety of heat-generating electronics devices or assemblies would be in great demand, especially one featuring high heat-transfer efficiency, small form factor, and simple structure for low-cost high-volume manufacture.

### SUMMARY OF INVENTION

The present invention advantageously introduces a boiling enhancement coating to a cooling module with liquid boiling and condensing. The boiling enhancement coating creates a microporous interface structure, as it is immersed under the liquid coolant in the cooling apparatus, providing a significant enhancement of nucleate boiling heat transfer and the critical heat flux over conventional boiling cooler. In this invention, a coating technique developed by You and O'Connor (1998) and later improved by You and Kim (2005) is used, wherein the coating comprising various sizes of cavity-generating particles bound by a thermally-conductive binder is made through an inexpensive and easy process. The coating technique is described further in U.S. Pat. No. 5,814,392, and in co-pending U.S. patent application Ser. No. 11/272,332, entitled “Thermally Conductive Microporous Coating”, filed on Nov. 9, 2005. Applicant hereby incorporates this patent and patent application by reference.

For particular liquid coolant type used, an optimized particle size of the coating can be controlled by the process. The porous surface structure is also insensitive to the coating thickness. Because of the substantial enhancement of the boiling heat transfer efficiency plus an easy and flexible coating process, the design of a cooling apparatus in combination with the boiling enhancement coating can be greatly simplified, with wide choices of working liquids, including water. No complicated radiator assembly is necessary and no need to use low-boiling point refrigerant as liquid coolant, making it very suitable for building a miniaturized and economic boiling cooler for cooling a heat-generating compact electronics element.

In one embodiment of the invention, a vessel comprises a single round pipe tower with a height less than 300 mm, containing water as a liquid coolant and a thermally-conductive side coated by the boiling enhancement coating immersed under water in the vessel. While other embodiments of the invention include the various design options for the vessel, choices of the coating techniques, particle sizes in coating, and liquid types are also described.

### BRIEF DESCRIPTION OF DRAWINGS

FIG. 1 is a cross-sectional view showing a cooling apparatus in combination with a boiling enhancement coating and a coupled heating element according to first embodiment of the invention.

FIG. 2A is a cross-sectional view showing the coating coupled to top surface of a thermally-conductive side within the vessel.

FIG. 2B is a SEM image of boiling enhancement Thermally Conductive Microporous Coating (TCMC) structures using particles of sizes of 30-50 μm.

FIG. 3 is a boiling result comparison with plain surface for the TCMC with particle sizes of 30-50 μm in saturated water at 60° C., referenced by the result for ABM coating.

FIG. 4 is a cross-sectional view showing schematically a cooling apparatus in combination with a boiling enhancement coating, according to another embodiment of the invention.

FIG. 5 is a cross-sectional view showing schematically a cooling apparatus with multiple pipe towers coupled to one chamber in combination with a boiling enhancement coating.

FIG. 6 is a cross-sectional view showing schematically a cooling apparatus in combination with a boiling enhancement coating, having an extended thermal conductive plate with multiple fins attached.

### DETAILED DESCRIPTION OF PREFERRED EMBODIMENT(S)

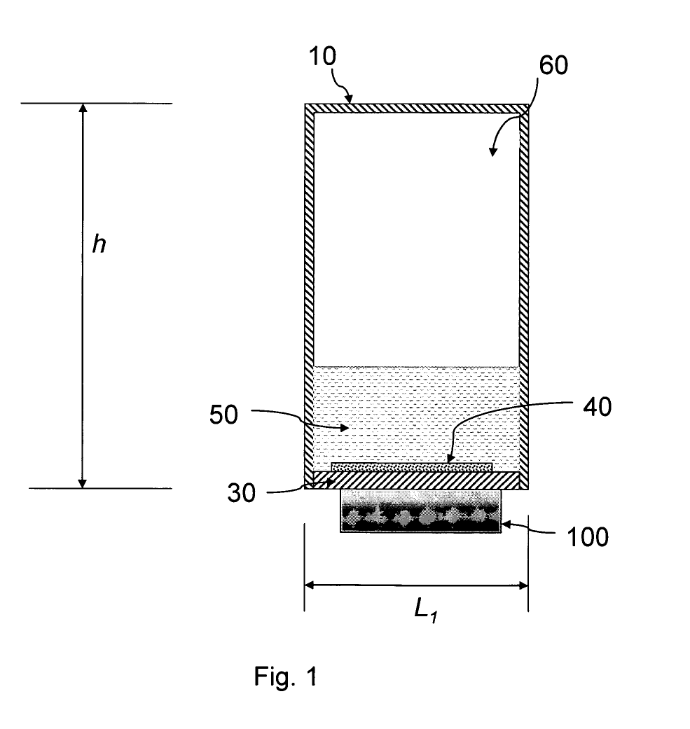

The current invention provides a basis for simplifying the design of a cooling apparatus using surface enhancement boiling heat transfer plus condensing liquid. While traditional boiling coolers use cavities or grooves to increase active nucleation sites, this invention uses a microporous surface coating for achieving significant boiling enhancement which greatly reduces the necessity for a radiator with complicated structure within the apparatus, making it possible to be miniaturized as a cooler for heating electronics elements. In one embodiment of the invention, a cooling apparatus in combination with a boiling enhancement coating with a most simplified configuration is shown in FIG. 1. It is a cross-section view of a vessel 10 with a shaped pipe tower with a height of h and/or a lateral dimension of L₁ less than or equal to 300 mm.

The vessel 10 is partially filled liquid coolant 50. A shaped plate 30 made of a thermally-conductive material is immersed under the liquid coolant 50, usually at just the bottom side of the vessel 10. A heat-generating element 100 that is to be cooled by the apparatus can be coupled to the plate 30 from outside the vessel 10 so that the heat flux flows from the heating element 100 to the apparatus by conduction. A microporous coating 40 for boiling enhancement has been applied to a surface of at least part of the plate 30 inside the vessel 10, which is immersed under liquid coolant 50. When receiving heat through conductive plate 30 from the heat-generating element 100, liquid 50 boils locally at the porous surface and vaporizes, transferring the heat into the surrounding bulk liquid. The vapor 60 from the boiling liquid rises into an empty space above liquid level in the vessel 10 and may condense back to liquid at a surface site, further transferring heat to the body of the vessel 10. Effectively, the heat-generating element 100 is cooled by the apparatus.

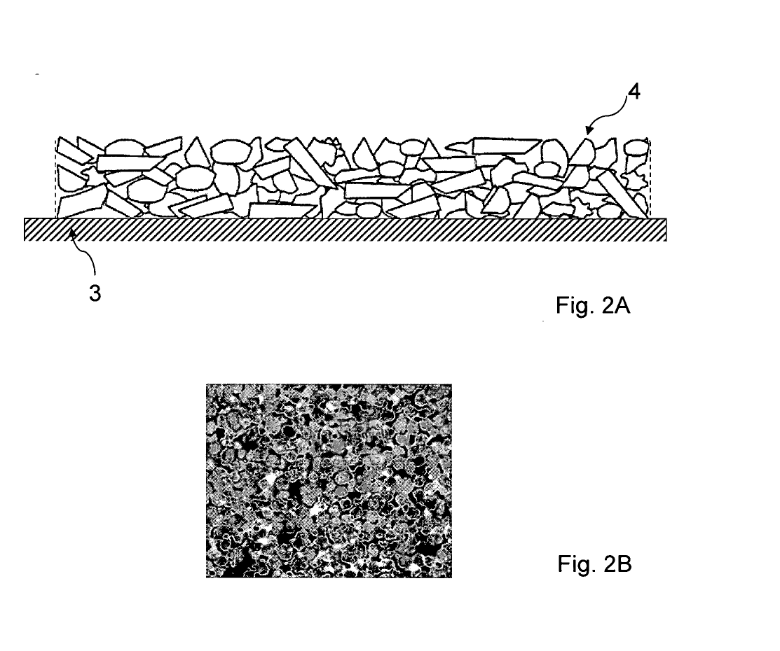

A preferred embodiment of the invention uses a Thermally-Conductive Microporous Coating (TCMC) developed by You and Kim (2005), described in patent application Ser. No. 11/272,332 in the cooling apparatus. This coating technique combines the advantages of a mixture batch type and thermally-conductive microporous structures. The microporous surface is created using particles of various sizes comprising any metal which can be bonded by the soldering process including nickel, copper, aluminum, silver, iron, brass, and various alloys in conjunction with a thermally conductive binder. The coating is applied on the surface of the shaped plate 30 (before installing it into the vessel 10 of the cooling apparatus) while mixed with a solvent. The solvent is vaporized after the application prior to heating the surface sufficiently to melt the binder to bind the particles. FIG. 2A shows a cross-sectional view of the coating structure full of cavities and particles formed on top of the substrate plate.

The mixture batch type application is an inexpensive and easy process, not requiring extremely high operating temperatures. The coating surface created by this process is insensitive to its thickness due to high thermal conductivity of the binder. Therefore, large size cavities can be constructed in the microporous structures for poorly wetting fluids, such as water, without causing serious degradation of boiling enhancement. This makes the cooling apparatus keep its high cooling efficiency for various types of working liquids simply by adjusting the size of metal particles to allow the size range of porous cavities formed fit well with the surface tension of the selected liquid to optimize boiling heat transfer performance. FIG. 2B shows a SEM picture of a coating surface containing nickel particles of sizes around 30-50 μm using −100+325 mesh nickel powder mixed with solder paste. As shown in the FIG. 2B, the solder pastes were clearly seen as a binder between nickel particles and resultantly produce numerous microporous cavities. The coating with such sized particles has been shown to provide superior boiling heat transfer performance for water as working liquid.

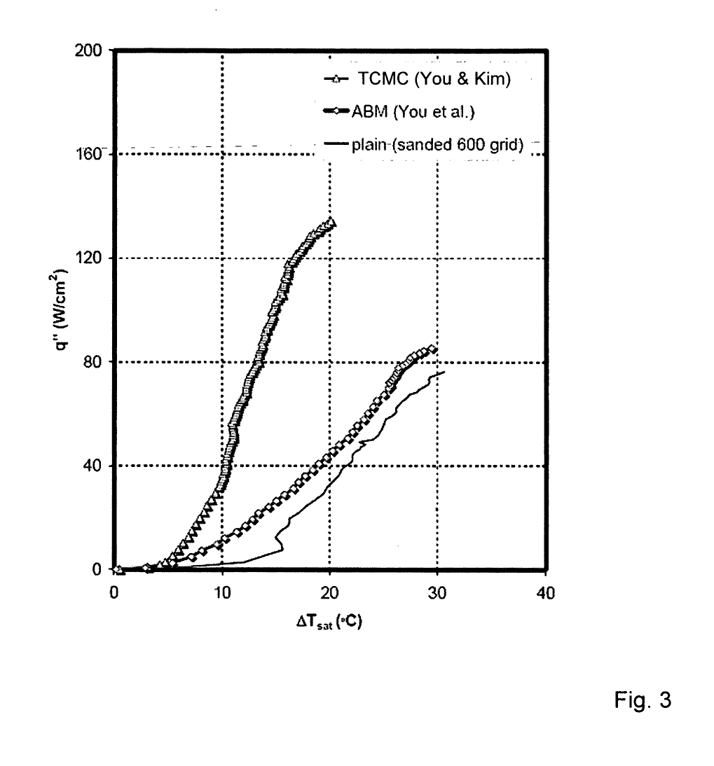

In one embodiment of the invention the cooling apparatus uses water as its working liquid coolant. FIG. 3 illustrates the data produced in nucleate boiling heat transfer test, comparing results between a surface using TCMC with 30-50 μm particles and a plain sand-roughened surface for saturated water at pressure of 2.89 psia (Tₛₐₜ=60° C.). Approximately 160% enhancement of nucleate boiling and 70% enhancement of critical heat flux were achieved for TCMC compared to plain surface. The boiling experiment data at Tₛₐₜ=60° C. are used considering electronic cooling applications such as computer chip cooling. Since water is a very poorly wetting liquid micro-size cavities formed in the coating must be sufficiently large, at least 30-50 μm for water, to activate the nucleation boiling sites. A prior ABM coating technique developed by You et al. (1998), described in U.S. Pat. No. 5,839,142 also shown in FIG. 3 as a reference, only enhanced nucleate boiling by 15% over the plain surface due to the smaller cavity sizes and no thermally-conductive binder in the coating. In addition, adding an extremely small amount (<0.01 g/l) nano-sized particles (such as alumina) into distilled or deionized water to make a so-called nano-fluid as the liquid coolant can further enhance the critical heat flux from the heated side with TCMC during the boiling. About 200% increase in critical heat flux is observed with such a nano-fluid comparing to the case using pure water as the liquid coolant.

For other liquid coolants, particle sizes in the coating can be optimized through similar tests for achieving a best boiling heat transfer performance. For example, smaller particle sizes such as 8-12 μm and 30-50 μm show higher enhancement of nucleate boiling heat transfer than larger particle sizes of 100-200 μm for saturated FC-72 (a chemical produced by 3M). These test results demonstrate that the cooling apparatus described in the invention is flexible enough to use a variety of liquid coolants. Particularly it shows that one embodiment of the invention using water as the liquid coolant can be used to make an inexpensive and environmentally-safe cooling apparatus for cooling a variety of electronics devices, modules, and systems.

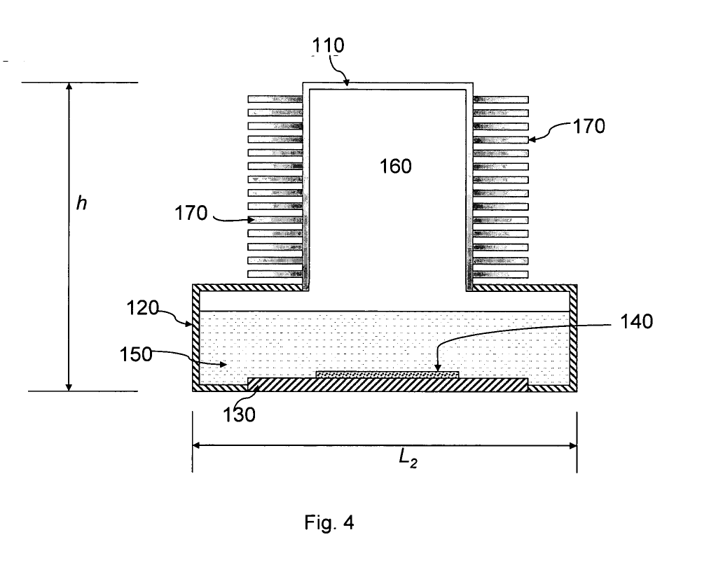

As a second embodiment of the invention, shown in FIG. 4, the cooling apparatus can be designed to have a chamber 120 with a larger lateral base dimension L₂ than L₁ of the vessel 10 mentioned in the first embodiment of the invention to hold more liquid coolant 150, and a bigger sized conductive plate 130 with a wider area of boiling enhancement coating 140, so that it has a larger heat capacity for cooling object with high heat intensity or bigger in physical dimension. As shown in FIG. 4, a shaped pipe tower 110 rises on top of this chamber 120 to provide extra passage for vapor 160 from boiling liquid to spread heat and extra surface sites for vapor 160 to condense back to liquid. Functionally the pipe tower 110 is the same as the above-liquid-level portion of the vessel 10 (in FIG. 1 with a single pipe tower) described in the first embodiment of the invention. In addition, multiple fin structures 170 are added to the outside surface of the pipe tower 110 for easier spreading of heat with convection. The details of the fin structures can be optimized in thermal design, and the pipe tower and fins are made of thermally conductive materials for achieving efficient heat dissipation.

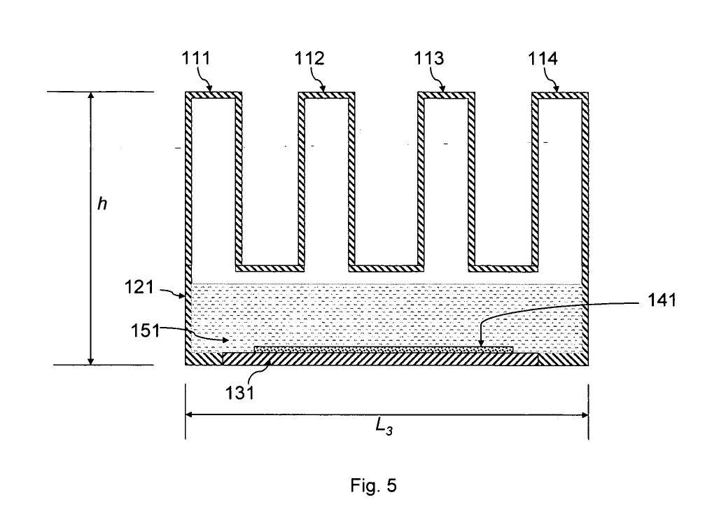

In a third embodiment of the invention, as shown in FIG. 5, multiple pipe towers, as illustrated by 111, 112, 113, and 114, each with one end to connect with the common base chamber 121 can be implemented into the cooling apparatus in combination with the boiling enhancement coating 141. Again, the advantage to the use of multiple pipe towers 111-114 relies on providing more rooms for vapor passage, more surface sites for condensation without necessarily increasing lateral dimension L₃ compared to the cooling apparatus with single pipe tower, and possibility adding extra fins for easier heat exchange by convection. Although the structure with multiple pipe towers 111-114 or extra fins is less suitable for volume manufacture than a single pipe tower, it may be necessary for minimizing the dimension of the whole apparatus for cooling small electronics elements but having high heat intensity.

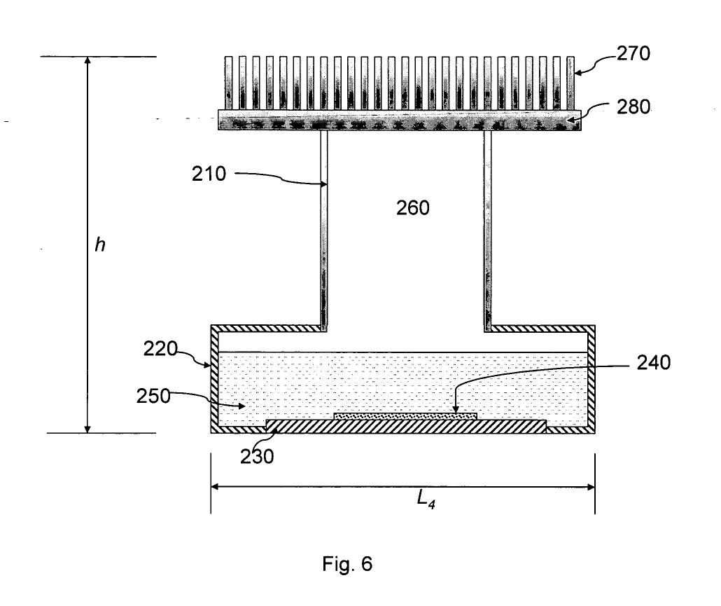

In FIG. 6, another embodiment of the invention, extended from one shown in FIG. 4, illustrates that a thermally conductive plate 280 is added on top of one pipe tower 210 to provide an extended surface of heat dissipation for the heated vapor within. Other components of the boiling cooler can be similar to those in FIG. 4, such as the chamber 220, liquid coolant 250, thermally conductive plate (at the surface in contact with the heat source) 230, and the boiling enhancement coating 240 on the plate 230 and at least partially submerged in the liquid coolant 250. The added plate 280 has a desired bulk volume to provide efficient heat conduction or a desired surface area for required heat dissipation or a desired shape to fit in the electronic system that needs cooling. Multiple fins 270 structure can be attached to this plate 280 for increasing surface profile to achieve optimum heat dissipation. The lateral dimension L₄ of the cooling apparatus depends on the heat element to be cooled.

An extension of the boiling cooling apparatus is to use active cooling. While other conventional active cooling apparatus uses single-phase cooling wherein the liquid medium being circulated around stays in liquid state, this invention uses two-phase active cooling by pumping vapor created by boiling working liquid to a condenser and cooled back to liquid. In various embodiments of the invention described, a connective tubing can be added to the pipe tower 10, 110, 111-114, connected to a pump. Vapor in the pipe tower is moved to a separate condenser by the pressure difference, and vapor is then condensed to liquid in the condenser and returned to the vessel as liquid again. In addition, this invention distinguishes itself by using liquid boiling to create vapor, particularly using microporous surface structures for boiling enhancement, rather than just using evaporation as in many conventional two-phase cooling apparatus.

Foregoing described embodiments of the invention are provided as illustrations and descriptions. They are not intended to limit the invention to the precise for described. In particular, it is contemplated that functional implementation of invention described herein may be implemented equivalently in hardware, software, firmware, and/or other available functional components or building blocks. Other variations and embodiments are possible in light of above teachings, and it is thus intended that the scope of invention not be limited by this Detailed Description, but rather by the following claims.

What is claimed is:

1. A cooling apparatus comprising:
a vessel with a height less than or equal to 300 mm, wherein the vessel comprises a thermally conductive side;
a liquid coolant at least partially filling the vessel; and
a boiling enhancement coating coupled to the thermally conductive side at a surface within the vessel.

2. The apparatus of claim 1, wherein a heat-generating electronics element to be cooled is coupled to the thermally conductive side at a surface outside the vessel.

3. The apparatus of claim 1, wherein a lateral dimension of the thermally conductive side coupled with a heat-generating element from outside the vessel is based on a lateral dimension of the heat-generating element.

4. The apparatus of claim 1, wherein the boiling enhancement coating on the surface of the thermally conductive side within the vessel is fully submerged in the liquid coolant.

5. The apparatus of claim 4, wherein the boiling enhancement coating comprises a microporous surface comprising cavity-generating particles of various sizes bound by a thermal conducting binder.

6. The apparatus of claim 4, wherein the boiling enhancement coating comprises particle sizes in an optimized sub-range within 8 m-200 μm for a particular liquid coolant type.

7. The apparatus of claim 1, wherein the liquid coolant is boiled by receiving heat from a heat-generating electronics element coupled to the thermally conductive side at a surface outside the vessel.

8. The apparatus of claim 7, wherein the liquid coolant is boiled locally at a porous surface created by the boiling enhancement coating.

9. The apparatus of claim 7, wherein boiling of the liquid coolant created by the boiling enhancement coating augments a heat transfer with a bulk liquid in the vessel.

10. The apparatus of claim 7, wherein the liquid coolant comprises refrigerant, alcohol, ammonia, or water.

11. The apparatus of claim 1, wherein a portion of the vessel above a level of the liquid coolant is used as a passage for vapor from a boiled liquid in the vessel to spread heat and further condense back to liquid.

12. The apparatus of claim 1, wherein the vessel further comprises an extended thermal conductive plate coupled to a surface of the vessel for increasing surface area of heat dissipation.

13. The apparatus of claim 1, wherein the vessel further comprises multiple fins affixed on a surface outside the vessel including an extended thermal conductive plate for optimum heat dissipation.

14. The apparatus of claim 1, wherein the cooling apparatus further comprises a pump for pumping vapor from liquid boiling in the vessel to a condenser through a connective tubing, cooling vapor to liquid in the condenser, and returning liquid back to the vessel through another tubing.

15. An apparatus for cooling a heat-generating element, comprising:
a chamber comprising a thermally conductive side;
water at least partially filling the chamber; and
a boiling enhancement coating coupled to the thermally conductive side on a surface within the chamber.

16. The apparatus of claim 15, wherein the boiling enhancement coating comprises a porous surface comprising 30-50 μm sized cavity-generating particles bound by a thermally conductive binder.

17. The apparatus of claim 15, wherein a surface of the boiling enhancement coating is coupled to the thermally conductive side on the surface within the chamber.

18. The apparatus of claim 15, wherein the boiling enhancement coating surface is at least partially immersed under water in the chamber.

19. The apparatus of claim 15, wherein the water as a liquid coolant comprises purified water or water doped with nano-sized particles.

20. The apparatus of claim 15, wherein the water is boiled by receiving heat from a heat-generating element coupled to the thermally conductive side at a surface outside the chamber.

21. The apparatus of claim 15, wherein the water is boiled locally at a microporous surface of the boiling enhancement coating.

22. The apparatus of claim 15, wherein water local boiling created by the boiling enhancement coating augments heat transfer with bulk water in the chamber.

23. The apparatus of claim 15, wherein the chamber further comprises one or more pipe towers wherein an end of each pipe tower is coupled to the chamber.

24. The apparatus of claim 23, wherein the pipe tower is not filled by bulk water and is used as a passage for vapor from the boiling water in the chamber to spread heat and condense back to liquid water at a surface within the tower.

25. The apparatus of claim 23, wherein the pipe tower further comprises an extended thermal conductive plate coupled to a surface of the pipe tower for increasing surface area of heat dissipation.

26. The apparatus of claim 23, wherein the pipe tower further comprise multiple fins affixed on a surface outside the pipe tower including an extended thermal conductive plate for optimum heat dissipation.

27. The apparatus of claim 15 further comprises a pump for pumping vapor from water boiling to a condenser through a connective tubing, cooling water vapor to liquid in the condenser, and returning water back to the chamber through another connective tubing.
